(19) United States
(12) Patent Application Publication
(10) Pub. No.: US 2026/0239749 A1
(43) Pub. Date: Aug. 13, 2026

(54) SINGLE-PHOTON AVALANCHE DIODES WITH AN INTEGRATED TRANSISTOR

(71) Applicant: GlobalFoundries Singapore Pte. Ltd., Singapore (SG)

(72) Inventors: Francesco Gramuglia, Augsburg (DE); Eng Huat Toh, Singapore (SG)

(21) Appl. No.: 19/047,699

(22) Filed: Feb. 7, 2025

(51) Int. Cl. H10F 30/225; H10F 39/00; H10F 71/00; H10F 77/00; H10F 77/20

(52) U.S. Cl. CPC H10F 30/225; H10F 39/80373; H10F 71/00; H10F 77/206; H10F 77/933

(57) ABSTRACT

Structures including a single-photon avalanche diode and methods of forming such structures. The structure comprises a semiconductor layer including a first trench and a second trench, and a single-photon avalanche detector including a first doped region in the semiconductor layer and a second doped region in the semiconductor layer. The second doped region adjoins the first doped region along a p-n junction. The structure further comprises a transistor including a first gate electrode inside the first trench and a second gate electrode inside the second trench.

### BACKGROUND

The disclosure relates to semiconductor device fabrication and integrated circuits and, more specifically, to structures including a single-photon avalanche diode and methods of forming such structures.

A single-photon avalanche diode (SPAD) is a type of solid-state photodetector belonging to the same device family as photodiodes and avalanche photodiodes. A fundamental difference between single-photon avalanche diodes and other types of photodetectors is that a single-photon avalanche diode is biased well above its reverse-bias breakdown voltage. When a single-photon avalanche diode is placed under such a high reverse bias, photon-initiated charge carriers are accelerated by the electric field to a kinetic energy that is large enough to knock electrons out of atoms of the bulk material and generate additional charge carriers that may exponentially grow to generate an avalanche of charge carriers. A single-photon avalanche diode can detect single photons providing short duration current pulses that can be counted or used to obtain a time of arrival of a particular incident single photon.

A transistor may be used in an electrical circuit to control the operation of the single-photon avalanche diode. The transistor, which tends to be large in size, consumes significant chip area that is additive to the significant chip area that is consumed by the large single-photon avalanche diode.

Improved structures including a single-photon avalanche diode and methods of forming such structures are needed.

### SUMMARY

In an embodiment of the invention, a structure comprises a semiconductor layer including a first trench and a second trench, and a single-photon avalanche detector including first and second doped regions in the semiconductor layer. The second doped region adjoins the first doped region along a p-n junction. The structure further comprises a transistor including a first gate electrode inside the first trench and a second gate electrode inside the second trench.

In an embodiment of the invention, a method comprises forming first and second trenches in a semiconductor layer, and forming a single-photon avalanche detector including first and second doped regions in the semiconductor layer. The second doped region adjoins the first doped region along a p-n junction. The method further comprises forming a transistor including a first gate electrode inside the first trench and a second gate electrode inside the second trench.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 is a top view of a structure at an initial fabrication stage of a processing method in accordance with embodiments of the invention.

FIG. 2 is a cross-sectional view taken generally along line 2 -2 in FIG. 1.

FIG. 3 is a cross-sectional view of the structure at a fabrication stage subsequent to FIGS. 1, 2.

FIG. 4 is a cross-sectional view of the structure at a fabrication stage subsequent to FIG. 3.

FIG. 5 is a cross-sectional view of the structure at a fabrication stage subsequent to FIG. 4.

FIG. 6 is a cross-sectional view of the structure at a fabrication stage subsequent to FIG. 5.

FIG. 7 is a cross-sectional view of the structure at a fabrication stage subsequent to FIG. 6.

FIG. 8 is a cross-sectional view of a structure in accordance with alternative embodiments of the invention.

### DETAILED DESCRIPTION

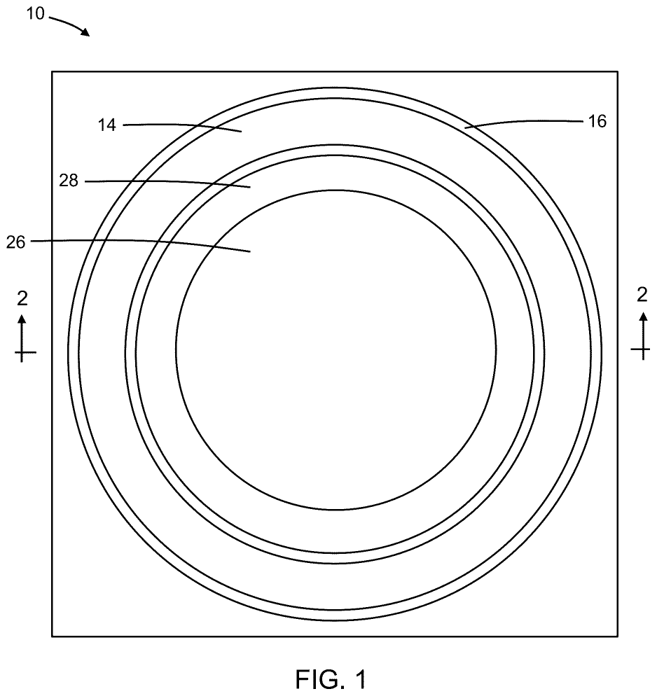

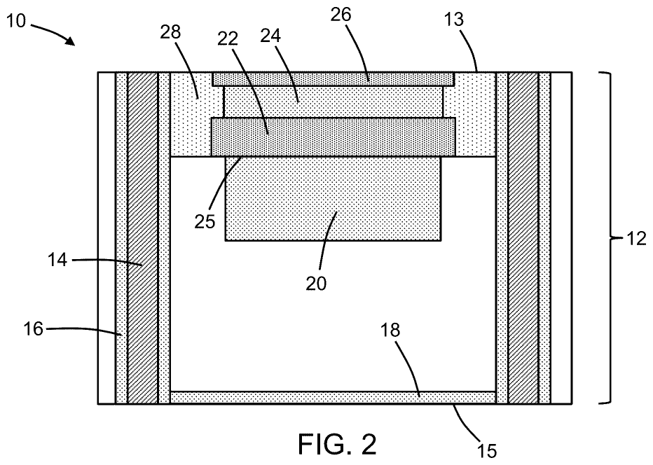

With reference to FIGS. 1, 2 and in accordance with embodiments of the invention, a structure 10 including a single-photon avalanche detector and a transistor may be formed using a semiconductor layer 12. In an embodiment, the semiconductor layer 12 may be comprised of a semiconductor material, such as single-crystal silicon, that is lightly doped with a p-type dopant. The semiconductor layer 12 may have a surface 13, a surface 15, and a thickness of its semiconductor material between the surface 13 and the surface 15.

A deep trench isolation region 14 may be formed in the semiconductor layer 12. In an embodiment, the deep trench isolation region 14 may be formed by applying and patterning a hardmask, etching a trench using the patterned hardmask, filling the trench with a dielectric material or a combination of polysilicon and a dielectric liner, and planarizing with chemical-mechanical polishing. A conductor region 16 may be formed at the sidewalls of the trench by, for example, ion implantation before the trench is filled. The deep trench isolation region 14 surrounds an active region of the semiconductor layer 12 in which the single-photon avalanche detector and transistor are integrated. The deep trench isolation region 14 may extend through the full thickness of the semiconductor layer 12 between the surface 13 and the surface 15.

A conductor region 18 may be formed by, for example, ion implantation at the surface 15 of the semiconductor layer 12. The conductor region 18 may be physically and electrically coupled to the conductor region 16. The conductor region 16 may extend along the length of the deep trench isolation region 16 from the conductor region 18 to the surface 13.

A doped region 20 is arranged as a deep well in a portion of the semiconductor layer 12. The doped region 20 is spaced in a vertical direction from the surface 13 of the semiconductor layer 12. In an embodiment, the doped region 20 may be formed by introducing a dopant by, for example, a masked ion implantation into the semiconductor layer 12. A patterned implantation mask may be formed to define a selected area (e.g., location and horizontal dimensions) on the surface 13 of the semiconductor layer 12 that is exposed for implantation to form the doped region 20. The implantation conditions, such as ion species, dose, and kinetic energy, may be selected to tune the electrical and physical characteristics of the doped region 20. In an embodiment, the doped region 20 may be doped with a concentration of a p-type dopant, such as boron, to provide p-type conductivity. The doped region 20 may have the same conductivity type as the semiconductor layer 12 but at a higher dopant concentration.

A doped region 22, a doped region 24, and a doped region 26 are arranged in portions of the semiconductor layer 12 between the doped region 20 and the surface 13 of the semiconductor layer 12. A doped region 28, which surrounds the doped regions 22, 24, 26, is peripherally arranged in the semiconductor layer 12 between the deep trench isolation region 14 and the doped regions 22, 24, 26. The doped region 26 is positioned between the doped region 24 and the surface 13, the doped region 24 is positioned between the doped region 22 and the doped region 26, and the doped region 22 is positioned between the doped region 24 and the doped region 20. The doped region 26 may have the same conductivity type as the doped region 22, and the doped region 24 may have the same conductivity type as the doped region 20. The doped region 20 and the doped region 22 adjoin along a p-n junction 25 of the single-photon avalanche detector.

In an embodiment, the doped region 22 may be formed as a well by introducing a dopant by, for example, a masked ion implantation of the semiconductor layer 12. A patterned implantation mask may be formed to define a selected area (e.g., location and horizontal dimensions) on the surface 13 of the semiconductor layer 12 that is exposed for implantation to form the doped region 22. The implantation conditions, such as ion species, dose, and kinetic energy, may be selected to tune the electrical and physical characteristics of the doped region 22. In an embodiment, the doped region 22 may be formed by introducing a dopant by, for example, a masked ion implantation into the semiconductor layer 12. In an embodiment, the doped region 22 may be doped with a concentration of an n-type dopant (e.g., arsenic or phosphorus) to provide n-type conductivity.

In an embodiment, the doped region 24 may be formed as a well by introducing a dopant by, for example, a masked ion implantation of the semiconductor layer 12. A patterned implantation mask may be formed to define a selected area (e.g., location and horizontal dimensions) on the surface 13 of the semiconductor layer 12 that is exposed for implantation to form the doped region 24. The implantation conditions, such as ion species, dose, and kinetic energy, may be selected to tune the electrical and physical characteristics of the doped region 24. In an embodiment, the doped region 24 may be doped with a concentration of a p-type dopant (e.g., boron) to provide p-type conductivity.

In an embodiment, the doped region 26 may be formed as a well by introducing a dopant by, for example, a masked ion implantation of the semiconductor layer 12. A patterned implantation mask may be formed to define a selected area (e.g., location and horizontal dimensions) on the surface 13 of the semiconductor layer 12 that is exposed for implantation to form the doped region 28. The implantation conditions, such as ion species, dose, and kinetic energy, may be selected to tune the electrical and physical characteristics of the doped region 24. In an embodiment, the doped region 22 may be doped with a concentration of an n-type dopant (e.g., arsenic or phosphorus) to provide n-type conductivity.

In an embodiment, the doped region 28 may be formed by introducing a dopant by, for example, a masked ion implantation of the semiconductor layer 12. A patterned implantation mask may be formed to define a selected area (e.g., location and horizontal dimensions) on the surface 13 of the semiconductor layer 12 that is exposed for implantation to form the doped region 24. The implantation conditions, such as ion species, dose, and kinetic energy, may be selected to tune the electrical and physical characteristics of the doped region 28. In an embodiment, the doped region 28 may be doped with a concentration of a p-type dopant (e.g., boron) to provide p-type conductivity. The doped region 28 may represent a guard ring surrounding the active region that functions to prevent surface breakdown arising from the operation of the single-photon avalanche detector in, or near, the reverse-bias breakdown voltage.

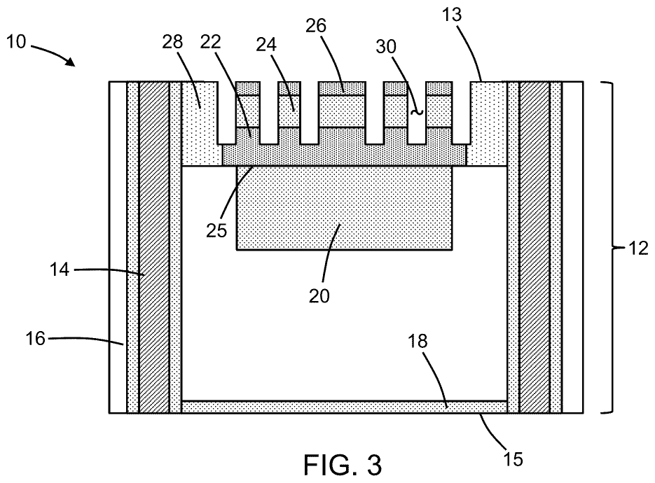

With reference to FIG. 3 in which like reference numerals refer to like features in FIGS. 1, 2 and at a subsequent fabrication stage of the processing method, trenches 30 are formed in the semiconductor layer 12 as openings that penetrate fully through the doped region 26, fully through the doped region 24, and through a portion of the doped region 22. The trenches 30 may be patterned by lithography and etching processes. To that end, an etch mask may be formed by a lithography process over the semiconductor layer 12. The etch mask may include a layer of a light-sensitive material, such as a photoresist, applied by a spin-coating process, pre-baked, exposed to light projected through a photomask, baked after exposure, and developed with a chemical developer to define openings at the locations of the subsequently-etched trenches 30. An etching process, such as a reactive ion etching process, is applied to form the trenches 30 at the location of the openings in the etch mask. The etch mask may be stripped by, for example, ashing after forming the trenches 30.

Each trench 30 may be annular in shape with inner and outer sidewalls that extend fully through the doped regions 24, 26 to a bottom inside the doped region 22. The trenches 30 may be concentric relative to the center of the active region, and the trenches 30 may be radially spaced from each other. The trenches 30 partition the doped region 26 into sections that represent source/drain regions of the transistor integrated into the structure 10 and the partitioned sections of the doped region 26 are radially spaced from each other. As used herein, the term “source/drain region” means a region of semiconductor material that can function as either a source or a drain of a transistor. One or more of the sections of the doped region 26 may also represent a terminal, such as an anode, of the single-photon avalanche detector. The trenches 30 partition the doped region 24 into sections that represent channel regions of the transistor that is integrated into the structure 10 and the partitioned sections of the doped region 24 are radially spaced from each other. The trenches 30 are radially positioned between the channel regions, the trenches 30 are radially positioned between the source/drain regions, and the source/drain regions are stacked with the channel regions. The doped region 22, which also adjoins the doped region 20 to form the p-n junction 25 of the single-photon avalanche detector, may represent a source/drain region of the transistor that is integrated into the structure 10.

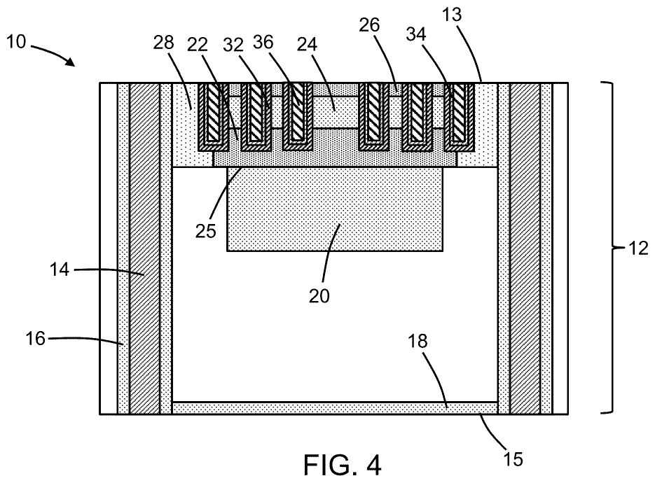

With reference to FIG. 4 in which like reference numerals refer to like features in FIG. 3 and at a subsequent fabrication stage of the processing method, a conductor region 32 and a dielectric layer 34 are formed at the sidewalls and bottom of each trench 30. The conductor region 32, which may be formed by ion implantation, may have the same conductivity type as the doped region 24. The dielectric layer 34 may be comprised of an oxide, such as silicon dioxide, that is an electrical insulator.

A conductor layer 36 is formed inside each trench 30 as a core that is arranged interior of the electrically-insulating trench liner represented by the dielectric layer 34. In an embodiment, the conductor layer 36 may be comprised of an electrically-conductive material that is deposited and planarized by chemical-mechanical polishing. In an embodiment, the conductor layers 36 may be comprised of polycrystalline silicon. In an embodiment, the conductor layers 36 may be comprised of a metal, such as a work function metal. The dielectric layer 34 is arranged inside each trench 30 between the conductor region 32 and the conductor layer 36 to provide electrical isolation. In particular, portions of the dielectric layer 34 are positioned between each conductor layer 36 and the doped regions 22, 24, 26. An upper portion of each conductor layer 36 may have a top surface that is coplanar or substantially coplanar with the surface 13 of the semiconductor layer 12. A lower portion of each conductor layer 36 may have a bottom surface that is coextensive with the bottom of one of the trenches 30.

The conductor layers 36 extend from the surface 13 toward the p-n junction 25 and, therefore, also from the surface 13 toward the surface 15. The conductor layers 36 are positioned in a vertical direction between the surface 13 and the surface 15. The p-n junction 25 is positioned in a vertical direction between the conductor layers 36 and the surface 15. The doped region 20 is fully positioned between the conductor layers 36 and the surface 15. The conductor layers 36 are separated by radial spaces, the sections of the doped region 24 representing the channel regions are arranged in the radial spaces between the conductor layers 36, and the sections of the doped region 26 representing the source/drain regions are also arranged in the radial spaces between the conductor layers 36. The sections of the doped region 24 are arranged in a vertical direction between the doped region 22 and the sections of the doped region 26.

The conductor layer 36 inside each trench 30 may provide a trench gate electrode of the transistor that is integrated into the structure 10. The dielectric layer 34 inside each trench 30 may provide a gate dielectric of the transistor that is integrated into the structure 10. Sections of the doped region 26 are respectively arranged between adjacent pairs of the conductor layers 36, and a section of the doped region 26 is arranged interior of the innermost conductor layer 36. Sections of the doped region 24 are respectively arranged between adjacent pairs of the conductor layers 36, and a section of the doped region 24 is arranged interior of the innermost conductor layer 36. The conductor layers 36, the sections of the doped region 24, and the sections of the doped region 26 may have a concentric arrangement.

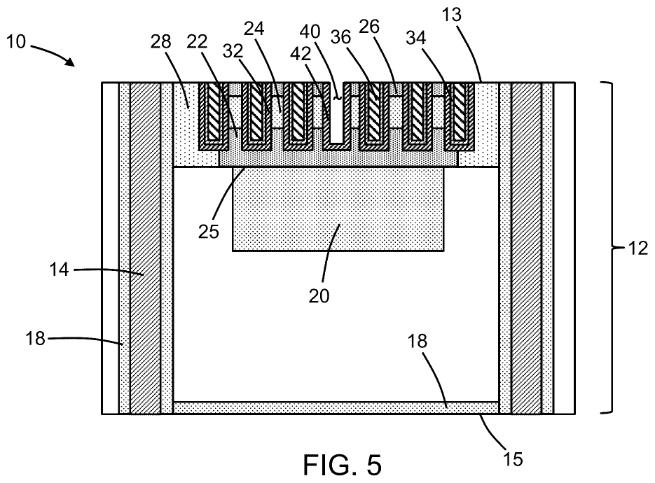

With reference to FIG. 5 in which like reference numerals refer to like features in FIG. 4 and at a subsequent fabrication stage of the processing method, a trench 40 is formed in the semiconductor layer 12 as an opening that penetrates fully through the doped region 26, penetrates fully through the doped region 24, and penetrates partially through the doped region 22. The trench 40 is surrounded by the conductor layers 36 and the trenches 30 in which the conductor layers 36 are formed.

The trench 40 may be patterned by lithography and etching processes. To that end, an etch mask may be formed by a lithography process over the semiconductor layer 12. The etch mask may include a layer of a light-sensitive material, such as a photoresist, applied by a spin-coating process, pre-baked, exposed to light projected through a photomask, baked after exposure, and developed with a chemical developer to define an opening at the location of the subsequently-etched trench 40. An etching process is used to form the trench 40 at the location of the opening in the etch mask. The etch mask may be stripped by, for example, ashing after forming the trench 40.

A dielectric layer 42 may be formed at the inner sidewall, outer sidewall, and bottom of the trench 40. The dielectric layer 42 may be comprised of an oxide, such as silicon dioxide, that is an electrical insulator.

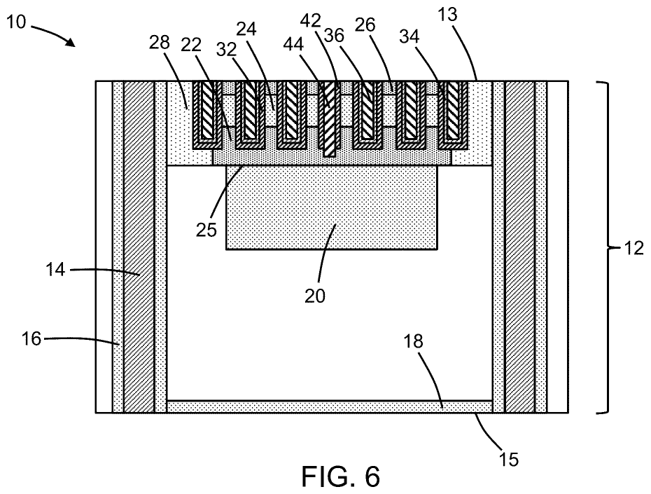

With reference to FIG. 6 in which like reference numerals refer to like features in FIG. 5 and at a subsequent fabrication stage of the processing method, the dielectric layer 42 may be selectively removed from the bottom of the trench 40 by a directional etching process to expose a portion of the semiconductor layer 12 at the bottom of the trench 40. Portions of the dielectric layer 42 on the sidewall of the trench 40 provide an electrically-insulating collar that is preserved and intact following the etching process. The selective removal of the dielectric layer 42 may extend the depth of the trench 40 further into the doped region 22.

A conductor layer 44 is formed inside the trench 40 as a core that is surrounded by the electrically-insulating collar represented by the dielectric layer 42. The conductor layer 44 may be comprised of a conductive material that is deposited and planarized by chemical-mechanical polishing. In an embodiment, the conductor layer 44 may be comprised of polycrystalline silicon. In an embodiment, the conductor layer 44 may be comprised of a metal. The conductor layer 44, which projects beyond the dielectric layer 42 on the sidewall of the trench 40, may be electrically coupled to the doped region 22 in the semiconductor layer 12 at the bottom of the trench 40. The trenches 30 and the conductor layers 36 inside the trenches 30 are arranged to surround the conductor layer 44 and, in an embodiment, the trenches 30 and the conductor layers 36 inside the trenches 30 may concentrically surround the conductor layer 44. The deep trench isolation region 14 surrounds the doped regions 20, 22, 24, 26, the conductor layers 36, and the conductor layer 44.

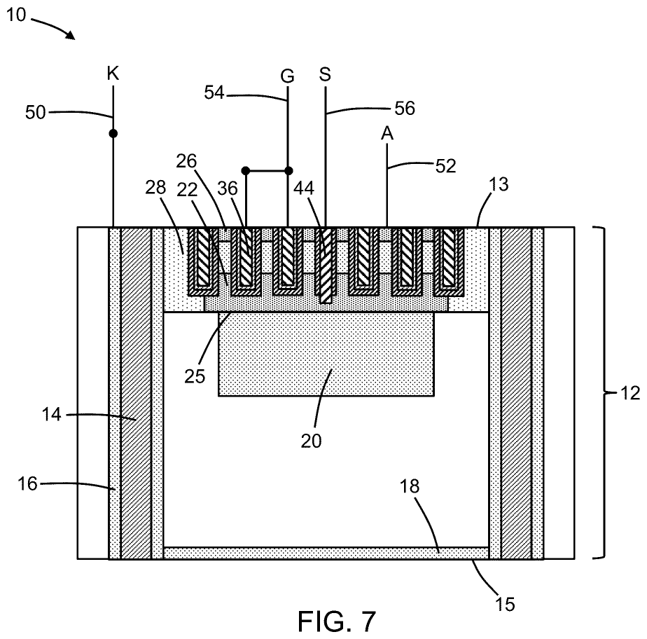

With reference to FIG. 7 in which like reference numerals refer to like features in FIG. 6 and at a subsequent fabrication stage of the processing method, an interconnect structure may be formed that includes electrical interconnections 50, 52, 54, 56 to the transistor and the single-photon avalanche detector embodied in the structure 10. The electrical interconnection 50 includes metal features that are physically and electrically coupled to the conductor regions 16, 18, which represents a terminal of the single-photon avalanche detector. The electrical interconnection 52 includes metal features that are physically and electrically coupled to a section of the doped region 26, which represents another terminal of the single-photon avalanche detector and a source/drain region of the transistor. In an embodiment, the conductor regions 16, 18 may represent a cathode (K) of the single-photon avalanche detector, and the section of the doped region 26 may represent an anode (A) of the single-photon avalanche detector and a source/drain region of the transistor. The electrical interconnection 54 is physically and electrically coupled to the conductor layers 36, which represent trench gate electrodes (G) of the transistor. The section of the doped region 26 representing the source/drain region is radially positioned between an adjacent pair of the trench gate electrodes. The electrical interconnection 56 is physically and electrically coupled to the conductor layer 44, which enables a sense node (S).

The structure 10 may be replicated to provide multiple instances of the single-photon avalanche diode and transistor, and these instances of the single-photon avalanche diode and transistor may be arranged as pixels in a pixel array to define, for example, an image sensor. The image sensor may be used in mobile phones, digital cameras, and other types of devices.

In use, the p-n junction between the doped region 20 and the doped region 22 of the single-photon avalanche diode may be reverse-biased by the integrated transistor above the breakdown voltage. The single-photon avalanche diode may be illuminated by light from the surface 15, and incident photons may be absorbed in the portions of the semiconductor layer 12 interior of the deep trench isolation region 14. The trenches 30 and the conductor layers 36 inside the trenches 30 may have a pattern that operates to reflect light escaping past the doped region 24 back toward the surface 15 and thereby increase the absorbed optical power. The reflection may be higher if conductor layers 36 comprise a metal instead of polysilicon. When an incident photon is absorbed, an electron-hole pair is created. An avalanche current is generated under the reverse bias by the creation of additional electron-hole pairs through impact ionization with atoms of the semiconductor material of the semiconductor layer 12. The current continues to be generated until the avalanche is quenched by lowering the bias below the breakdown voltage. The current provides a measurable electronic signal. To prepare for detecting another photon, the reverse bias may be raised again by the integrated transistor above the breakdown voltage to reset the single-photon avalanche diode. The conductor layer 44 enables an implementation of a sense node for continuous time monitoring of the p-n junction during use, and the conductor layer 44 may be coupled to an external buffer.

The structure 10 may be more compact and have a smaller form factor than conventional single-photon avalanche diodes because a transistor is integrated into the active region of the single-photon avalanche diode and used to control the operation of the single-photon avalanche diode. For example, the integrated transistor may function to control the reverse-biasing of the p-n junction above the breakdown voltage, the quenching of the single-photon avalanche diode, and the resetting of the single-photon avalanche diode. The integration of the transistor into the active region of the single-photon avalanche diode may also function to reduce parasitics. The pattern for the trenches 30 and the conductor layers 36 inside the trenches 30 may be optimized to provide a diffraction grating that improves the sensitivity by increasing the light path.

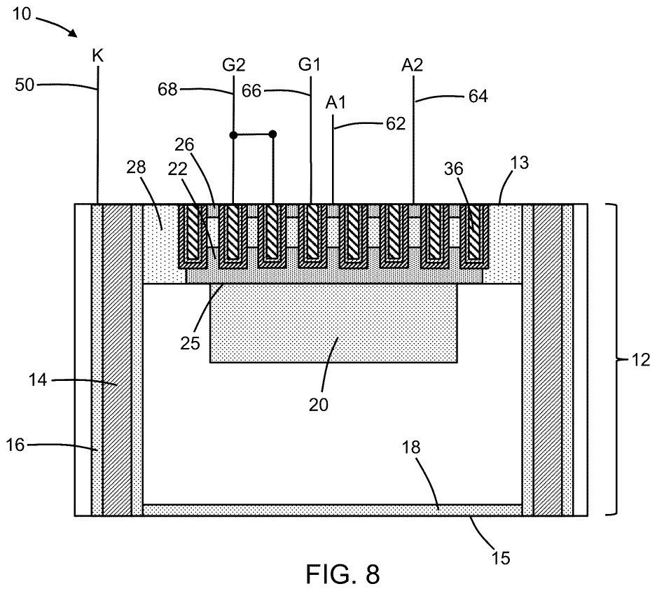

With reference to FIG. 8 and in accordance with alternative embodiments, the structure 10 may be modified to integrate multiple transistors and to eliminate the conductor layer 44. In an embodiment, the structure 10 may include additional instances of the vertical gate electrodes represented by the conductor layers 36 formed in the space formerly occupied by the eliminated conductor layer 44.

The interconnect structure may include an electrical interconnection 62 having metal features that are physically and electrically coupled to a section of the doped region 26, which represents a terminal of the single-photon avalanche detector and a source/drain region of a first transistor integrated into the structure 10. In an embodiment, the conductor regions 16, 18 may represent a cathode (K) of the single-photon avalanche detector, and the section of the doped region 26 may represent an anode (A1) of the single-photon avalanche detector and a source/drain region of the first transistor integrated into the structure 10. The interconnect structure may include an electrical interconnection 66 having metal features that are physically and electrically coupled physically and electrically coupled to one of the conductor layers 36, which represents a trench gate electrode of the first transistor that is integrated into the structure 10 and which surrounds the section of the doped region 26 representing the associated source/drain region.

The interconnect structure may include an electrical interconnection 64 having metal features that are physically and electrically coupled to a section of the doped region 26, which represents a terminal of the single-photon avalanche detector and a source/drain region of a second transistor integrated into the structure 10. In an embodiment, the section of the doped region 26 may represent another anode (A2) of the single-photon avalanche detector and a source/drain region of the second transistor integrated into the structure 10. The interconnect structure may include an electrical interconnection 68 having metal features that are physically and electrically coupled to a set of the conductor layers 36, which represent trench gate electrodes of the second transistor that is integrated into the structure 10. The section of the doped region 26 representing the source/drain region is radially positioned between the conductor layers 36. The conductor layers 36 associated with the second transistor surround the conductor layer 36 associated with the first transistor. In an embodiment, the conductor layers 36 associated with the second transistor and the conductor layer 36 associated with the first transistor may be concentric.

One of the integrated transistors may function as a transfer gate that is coupled to an external buffer. The other of the integrated transistors may function to control the reverse-biasing of the p-n junction above the breakdown voltage, the quenching of the single-photon avalanche diode, and the resetting of the single-photon avalanche diode.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value or precise condition as specified. In embodiments, language of approximation may indicate a range of +/−10% of the stated value(s) or the stated condition(s).

References herein to terms such as “vertical”, “horizontal”, etc. are made by way of example, and not by way of limitation, to establish a frame of reference. The term “horizontal” as used herein is defined as a direction or a plane parallel to a conventional plane of a semiconductor substrate, regardless of its actual three-dimensional spatial orientation. The terms “vertical” and “normal” refer to a direction or plane in the frame of reference perpendicular to the horizontal plane, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or “directly contacting” another feature if intervening features are absent. A feature may be “indirectly on” or in “indirect contact” with another feature if at least one intervening feature is present. Different features may “overlap” if a feature extends over, and covers a part of, another feature. A feature may “overlie” another feature if a feature is positioned “over” another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a semiconductor layer including a first trench and a second trench;
a single-photon avalanche detector including a first doped region in the semiconductor layer and a second doped region in the semiconductor layer, the second doped region adjoining the first doped region along a p-n junction; and
a first transistor including a first gate electrode inside the first trench and a second gate electrode inside the second trench.

2. The structure of claim 1 wherein the semiconductor layer includes a first surface, and the first gate electrode and the second gate electrode are positioned between the first surface and the second doped region.

3. The structure of claim 2 wherein the semiconductor layer includes a second surface opposite from the first surface, and the first gate electrode and the second gate electrode extend from the first surface toward the second surface.

4. The structure of claim 3 wherein the p-n junction is positioned between the first gate electrode and the second surface, and the p-n junction is positioned between the second gate electrode and the second surface.

5. The structure of claim 2 wherein the first gate electrode and the second gate electrode extend from the first surface toward the p-n junction.

6. The structure of claim 2 wherein the first gate electrode and the second gate electrode project into the first doped region.

7. The structure of claim 6 wherein the first transistor includes a dielectric layer having a first portion and a second portion, the first portion of the dielectric layer is positioned between the first gate electrode and the first doped region, and the second portion of the dielectric layer is positioned between the second gate electrode and the first doped region.

8. The structure of claim 6 wherein the semiconductor layer includes a second surface opposite from the first surface, the second doped region is positioned fully between the first gate electrode and the second surface, and the second doped region is positioned fully between the second gate electrode and the second surface.

9. The structure of claim 6 wherein the first doped region includes a first portion between the first gate electrode and the p-n junction, and the first doped region includes a second portion between the second gate electrode and the p-n junction.

10. The structure of claim 1 wherein the semiconductor layer includes a third trench, and further comprising:
a conductor layer inside the third trench, the conductor layer electrically coupled to the first doped region.

11. The structure of claim 10 wherein the first gate electrode and the second gate electrode surround the conductor layer.

12. The structure of claim 1 wherein the semiconductor layer includes a third trench, and further comprising:
a second transistor including a gate electrode inside the third trench.

13. The structure of claim 12 wherein the first gate electrode of the first transistor surrounds the gate electrode of the second transistor.

14. The structure of claim 1 further comprising:
a deep trench isolation region that surrounds the first doped region, the second doped region, the first gate electrode, and the second gate electrode.

15. The structure of claim 1 wherein the first transistor includes a channel region between the first gate electrode and the second gate electrode, the first gate electrode and the second gate electrode are separated by a radial space, and the channel region is arranged in the radial space between the first gate electrode and the second gate electrode.

16. The structure of claim 15 wherein the semiconductor layer includes a first surface and a second surface opposite from the first surface, the first gate electrode extends from the first surface toward the second surface, and the first gate electrode extends from the first surface toward the second surface.

17. The structure of claim 1 wherein the first transistor includes a channel region between the first gate electrode and the second gate electrode, and the first doped region is positioned between the channel region and the p-n junction.

18. The structure of claim 17 wherein the first transistor includes a source/drain region between the first gate electrode and the second gate electrode, and the channel region is positioned between the source/drain region and the first doped region.

19. The structure of claim 1 wherein the first gate electrode and the second gate electrode comprise a metal.

20. A method comprising:
forming a first trench and a second trench in a semiconductor layer;
forming a single-photon avalanche detector including a first doped region in the semiconductor layer and a second doped region in the semiconductor layer, wherein the second doped region adjoins the first doped region along a p-n junction;
forming a deep trench isolation region surrounding the first doped region, the second doped region, and the first trench; and
forming a transistor including a first gate electrode inside the first trench and a second gate electrode inside the second trench.
